(19) United States
(12) Patent Application Publication
(10) Pub. No.: US 2007/0114677 A1
(43) Pub. Date: May 24, 2007

(54) Semiconductor package with heat sink, stack package using the same and manufacturing method thereof

(75) Inventors: Heung-Kyu Kwon, Seongnam-si (KR); Tae-Hun Kim, Asan-si (KR); Sung-Yong Park, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/434,143

(22) Filed: May 16, 2006

(30) Foreign Application Priority Data
Nov. 24, 2005 (KR) 2005-113113

(51) Int. Cl. H01L 23/28

(52) U.S. Cl. 257/796; 257/E23.092

(57) ABSTRACT

A semiconductor package may include a heat sink. The heat sink may be disposed above and spaced apart from a substrate, which may support a semiconductor chip. The heat sink may have a hole. A liquid molding compound may be provided through the hole of the heat sink to form an encapsulant. The encapsulant may seal the semiconductor chip, leaving an upper portion of the heat sink exposed. A tape supporting the heat sink may be provided on the substrate. The tape may be removed after the encapsulant is provided.

### PRIORITY STATEMENT

This U.S. non-provisional application claims benefit of priority under 35 U.S.C. §119 from Korean Patent Application No. 2005-113113, filed on Nov. 24, 2005, the entire contents of which are incorporated herein by reference.

### BACKGROUND

1. Field of the Invention

Example embodiments of the present invention relate in general to semiconductor packaging technology, and more particularly, to a semiconductor package with a heat sink and a stack package using the semiconductor package and a method for manufacturing the semiconductor package.

2. Description of the Related Art

Techniques and designs may be pursued to provide electronic products that may (among other things) be small, light, fast, efficient, operate at high speeds, provide multiple functions and/or result in improved performance, at an effective cost.

To increase the capacity of semiconductor chips and decrease package size, cells may be arranged in a limited area of a semiconductor chip. According to one technology, a 3-D type semiconductor package may involve stacking semiconductor chips and/or semiconductor packages.

3-D stack chip packages may include a package having a plurality of semiconductor chips stacked on each other. Chip stacking may, however, negatively impacted production rates. For example, faulty chips may impact production rates because a single faulty chip among a stack of semiconductor chips may cause the whole stack of semiconductor chips to be faulty and non-repairable. Chips may not be validated until after they have been included in a package.

One solution to the faulty stack problem may involve stacking packages instead of chips. Although a stack of packages may be thicker than a stack of chips (because each chip may include its own package), each package may be individually validated prior to stacking, thus avoiding the reliability and/or production rate problems caused by chip stacking.

By way of example only, a stack package may include ball grid array (BGA) semiconductor packages. An upper package may be stacked on a lower package such that conductive bumps of the upper package may be connected to connection pads of the lower package. The connection pads of the lower package may be arranged over an upper surface of a wiring substrate and outside of an encapsulant. Accordingly, the encapsulant may be provided by injecting a liquid molding compound through a top gate of a mold assembly.

A conventional heat radiating technique may involve attaching a heat sink to an upper surface of the wiring substrate. The heat sink may cover a semiconductor chip and bonding wires. A portion of the heat sink may be bonded to the upper surface of the wiring substrate. An encapsulant may be formed by injecting a liquid molding compound through a top gate hole provided in the heat sink.

The upper surface of the wiring substrate may have a chip mounting area, a substrate pad area and a connection pad area. It may be difficult to arrange a heat sink attaching area in a limited area of the upper surface of the wiring substrate. One approach may involve increasing the size of the wiring substrate, but this may result in the increased size of a semiconductor package.

Further, flashes may occur when injecting a liquid molding compound through a top gate hole of the heat sink. The flashes may remain around the top gate hole and a positioning hole. Thus, a separate process may be implemented to remove the flashes. To reduce the likelihood of flashes, a heat sink may be in close contact with a cavity of an intermediate mold during a top gate molding process. From a practical standpoint, a gap between the cavity of the intermediate mold and the heat sink may exist as a result of many factors. Such factors may include, for example the shape of the heat sink and/or the thickness of an adhesive layer interposed between the heat sink and the wiring substrate. By virtue of the gap, flashes may be generated.

### SUMMARY

According to an example, non-limiting embodiment, a semiconductor package may include a substrate having an upper surface and a lower surface opposite to the upper surface. A semiconductor chip may be mounted on the upper surface of the substrate. An encapsulant may seal the semiconductor chip. A heat sink may be provided on the encapsulant and spaced apart from the substrate. The heat sink may have a hole. A portion of the heat sink may be exposed by the encapsulant.

According to another example, non-limiting embodiment, a method may involve providing a substrate supporting a semiconductor chip. A tape supporting a heat sink may be positioned above the semiconductor chip. The heat sink may have a hole. A liquid molding compound may be provided through the hole to seal the semiconductor chip, leaving a portion of the heat sink exposed. The tape may be removed.

According to another example, non-limiting embodiment, A semiconductor package may include a substrate. A semiconductor chip may be mounted on substrate. An encapsulant may seal the semiconductor chip. A heat sink may be provided on the encapsulant and spaced apart from the substrate. A portion of the heat sink may be exposed by the encapsulant.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements.

FIG. 1 is a plan view of a semiconductor package with a heat sink in accordance with an example, non-limiting embodiment of the present invention.

FIG. 2 is a cross-sectional view taken along the line II-II of FIG. 1.

FIGS. 3 through 5 are schematic views of a method that may be implemented to manufacture a semiconductor package in accordance with an example, non-limiting embodiment of the present invention.

FIG. 6 is a cross-sectional view of a stack package that may implement a semiconductor package in accordance with an example, non-limiting embodiment of the present invention.

The drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example, non-limiting embodiments of the invention.

### DETAILED DESCRIPTION OF EXAMPLE, NON-LIMITING EMBODIMENTS

Example, non-limiting embodiments of the present invention will be described more fully with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

Well-known structures and processes are not described or illustrated in detail to avoid obscuring the present invention.

An element is considered as being mounted (or provided) “on” another element when mounted or provided) either directly on the referenced element or mounted (or provided) on other elements overlaying the referenced element. Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

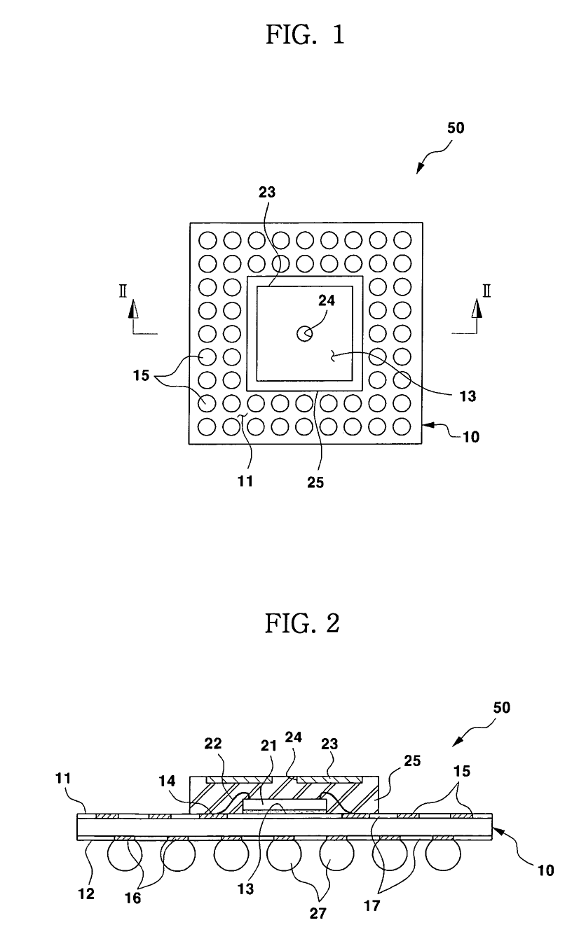

FIG. 1 is a plan view of a semiconductor package 50 with a heat sink 23 in accordance with an example, non-limiting embodiment of the present invention. FIG. 2 is a cross-sectional view taken along the line II-II of FIG. 1.

Referring to FIGS. 1 and 2, the semiconductor package 50 may be a BGA semiconductor package, for example. The semiconductor package 50 may include a wiring substrate 10 having an upper surface 11 and a lower surface 12. A semiconductor chip 21 may be mounted on the upper surface 11. Conductive bumps 27 may be provided on the lower surface 12. By way of example only, the conductive bumps 27 may be in the form of solder balls. An encapsulant 25 may be provided on the upper surface 11 of the wiring substrate 10 to seal the semiconductor chip 21. The upper surface 11 of the wiring substrate 10 may support connection pads 15. The connection pads 15 may be arranged on the outside of the encapsulant 25. The heat sink 23 may be disposed on the encapsulant 25 and above the semiconductor chip 21.

The upper surface 11 and the lower surface 12 may face in opposite directions. The upper surface 11 may have a chip mounting area 13. Substrate pads 14 may be provided on the upper surface 11 around the chip mounting area 13. The connection pads 15 may be provided on the upper surface 11 around the substrate pads 14. Bump pads 16 may be provided on the lower surface 12. A dielectric layer 17 may be provided on the upper surface 11 and the lower surface 12. The dielectric layer 17 may be fabricated from a photo solder resist, for example. The substrate pads 14, the connection pads 15 and the bump pads 16 may be exposed through the dielectric layer 17. Although not shown, the substrate pad 14 may be electrically connected to the connection pad 15 by a wiring layer (for example) and the connection pad 15 may be electrically connected to the bump pad 16 by a via (for example).

The wiring substrate 10 may be a printed circuit board, a tape wiring substrate, a ceramic substrate and a silicon substrate, for example.

Bonding wires 22 may electrically connect the semiconductor chip 21 to the substrate pads 14.

The heat sink 23 may have a plate shape (for example) and may have a gate hole 24. A heat sink 23 having another shape may be suitably implemented. The heat sink 23 may be disposed above (and spaced apart from) the semiconductor chip 21. The heat sink 23 may be located above (and spaced apart from) the bonding wire 22. In this example embodiment, the heat sink 23 may have a size sufficient to cover at least the semiconductor chip 21. The heat sink 23 may of course be of a smaller size. The heat sink 23 may radiate heat generated by the semiconductor chip 21. By way of example only, the gate hole 24 may be provided in a central area of the heat sink 23. In an alternative embodiment, the gate hole 24 may be provided in a peripheral area of the heat sink 23. It will be appreciated that more than one gate hole 24 may be provided in the heat sink 23.

The heat sink 23 may be fabricated from a material having good heat conductivity. For example the heat sink 23 may be fabricated from a metal such as Cu, Al, CuW, AlSiC, AlN, and/or BeO, for example. Further, the heat sink 23 may be coated with a metal such as Ni, Au, Ag, Sn and/or Cr, for example.

The encapsulant 25 may be provided by injecting a liquid molding compound through the gate hole 24 and onto the upper surface 11 of the wiring substrate 10. The encapsulant 25 may seal the semiconductor chip 21, the substrate pads 14 and the bonding wires 22. An upper portion of the heat sink 23 may be exposed by the encapsulant 25.

In this example embodiment, the heat sink 23 may directly contact the encapsulant 25. Such direct contact may improve heat radiation characteristics as compared to a structure in which an adhesive layer may be interposed between a heat sink and the encapsulant.

The conductive bumps 27, which may serve as external connection terminals, may be provided on the bump pads 16 of the lower surface 12 of the wiring substrate 10.

The heat sink 23 may be disposed above (and spaced apart from) the wiring substrate. In this way, a heat sink attaching area may not be provided on the upper surface 11 of the wiring substrate 10. Therefore, the semiconductor package 50 may secure a connection pad area without increasing the size of the wiring substrate 10.

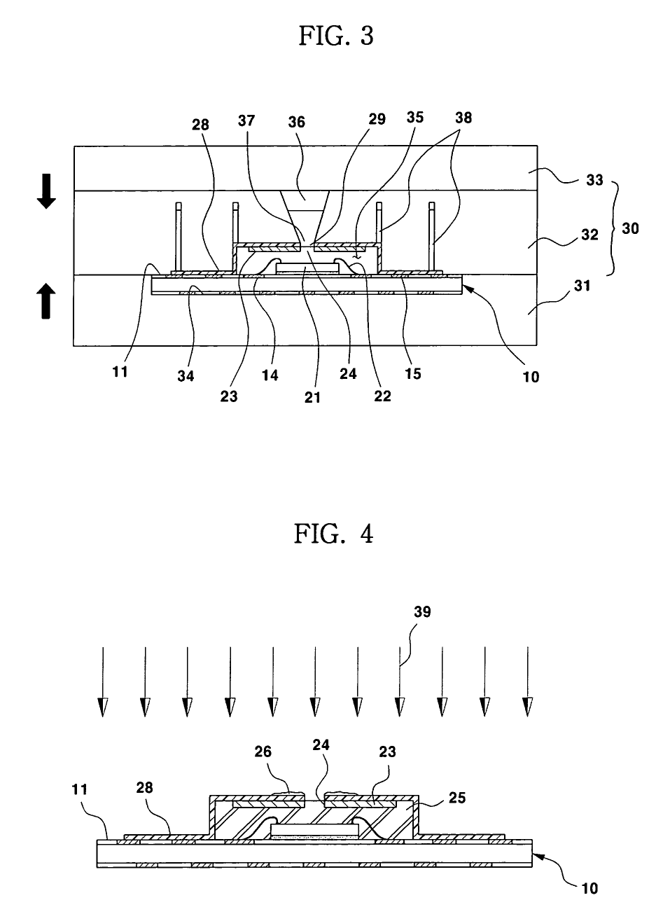

FIGS. 3 through 5 are schematic views of a method that may be implemented to manufacture a semiconductor package in accordance with an example, non-limiting embodiment of the present invention. Although this example embodiment shows a wiring substrate for a single semiconductor package, a matrix-type wiring substrate for a plurality of semiconductor packages may be implemented.

Referring to FIG. 3, a wiring substrate 10 may be prepared. A semiconductor chip 21 may be mounted on the wiring substrate 10. Bonding wires 22 may connect the semiconductor chip 21 to substrate pads 14 of the wiring substrate 10. The preparation of the wiring substrate 10 may be achieved via conventional processes, and therefore a detailed description of the same is omitted.

The wiring substrate 10 may be loaded into a mold assembly 30. The mold assembly 30 may include a bottom mold 31, an intermediate mold 32 and a top mold 33. The bottom mold 31 may have a recess for receiving the wiring substrate 10. The intermediate mold 32 may have a cavity 35 for forming an encapsulant, and a runner 36 and a gate 37 that may open into the cavity 35. The intermediate mold 32 may have suction holes 38 to position a tape 28. The tape 28 may support a heat sink 23. The suction holes 38 may be arranged corresponding to edges of the cavity 35 and a peripheral portion of the tape 28 to achieve stable contact between the tape 28 and the intermediate mold 32.

The intermediate mold 32 (supporting the tape 28) may be aligned between the bottom mold 31 and the top mold 33. The tape 28, which may support the heat sink 23, may have a window 29 corresponding to a gate hole 24 in the heat sink 23. The tape 28 may be secured in position on the intermediate mold 32 by drawing a vacuum through the suction holes 38. The heat sink 23 may be arranged corresponding to the cavity 35 of the intermediate mold 32 and the gate hole 24 may be connected to the gate 37 of the intermediate mold 32.

The tape 28 may be a UV tape, for example. The tape 28 may be removed after a molding process.

The wiring substrate 10 may be loaded into the recess 34 of the bottom mold 31. The bottom mold 31 may be engaged with the intermediate mold 32, which may be engaged with the top mold 33. The semiconductor chip 21 on the wiring substrate 10 may be located in the cavity 35.

A liquid molding compound may be injected through the runner 36 and the gate 37 of the intermediate mold 32, through the gate hole 24 of the heat sink 23, and into the cavity 35. The liquid molding compound may be cured to form an encapsulant 25. The molding compound may be an epoxy molding compound, for example. The tape 28 may surround the cavity 35 and cover the connection pads 15. In this way, the tape 28 may reduce the likelihood of flashes.

After a molding process, the bottom mold 31, the intermediate mold 32 and the top mold 33 may be separated from each other. The wiring substrate 10 having the encapsulant 25 may be unloaded from the bottom mold 31.

In this example embodiment, the intermediate mold 32 may be transferred between the bottom mold 31 and the top mold 33. In alternative embodiments, the intermediate mold 32 having the tape 28 may be aligned after the wiring substrate 10 is provided on the bottom mold 31.

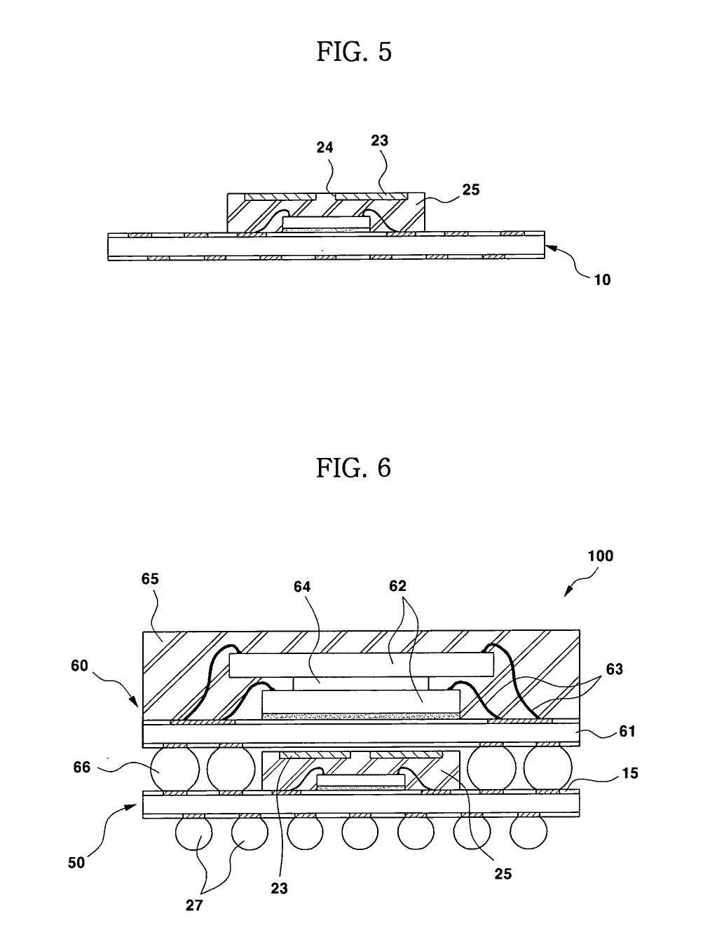

Referring to FIGS. 4 and 5, the tape 28 may be removed. As shown in FIG. 4, an upper surface 11 of the wiring substrate 10 supporting the tape 28 may be irradiated by ultraviolet rays 39. The adhesive strength between the tape 28 and the heat sink 23 and between the tape 28 and the wiring substrate 10 may be weakened. As shown in FIG. 5, the tape 28 may be removed from the wiring substrate 10 and the heat sink 23.

Flashes 26 may be provided on the tape 28. The flashes 26 may be removed together with the tape 28.

Conductive bumps 27 may be provided as shown in FIG. 2. For example, a flux may be applied to a bump pad 16 of the wiring substrate 10 and a conductive bump 27 may be provided on the bump pad 16. The conductive bump 27 may be reflowed. The conductive bump 27 may be fabricated from a solder material, Ni and/or Au.

FIG. 6 is a cross-sectional view of a stack package 100 that may implement a semiconductor package 50 in accordance with an example, non-limiting embodiment of the present invention.

Referring to FIG. 6, the stack package 100 may include a lower package 50 and an upper package 60. Connection pads 15 of the lower package 50 may be joined to conductive bumps 66 of the upper package 60.

The upper package 60 (in this example, a chip stack package) may include a wiring substrate 61 and two semiconductor chips 62 may be stacked on the wiring substrate 61. A spacer 64 may be interposed between the semiconductor chips 62. Bonding wires 63 may electrically connect the semiconductor chips 62 to the wiring substrate 61. An encapsulant 65 may seal the semiconductor chips 62 and the bonding wires 63. Conductive bumps 66 may be provided on a lower surface of the wiring substrate 61. The diameter of the conductive bumps 66 of the upper package 60 may be larger than the height of the encapsulant 25 of the lower package 50. In this way, the wiring substrate 61 of the upper package 60 may be spaced apart from the encapsulant 25 of the lower package 50.

Heat generated in the lower package 50 during operation of the stack package 100 may be radiated externally through the conductive bumps 27 and the heat sink 23 of the lower package 50.

Although this example embodiment shows a BGA type chip stack package as the upper package 60, the upper package 60 may not be limited in this regard.

In accordance with the example, non-limiting embodiments of the present invention, a heat sink may be disposed above (and spaced apart from) a wiring substrate, thereby eliminating the need of forming a heat sink attaching area on an upper surface of a wiring substrate. Therefore, a semiconductor package may provide a connection pad area without increasing the size of a wiring substrate.

A tape may be implemented to support the heat sink. The tape may be removed after providing an encapsulant. In this way, flashes which may occur around a gate hole in the heat sink may be removed together with the tape.

Example, non-limiting embodiments of the present invention have been described in detail. It will be understood that many variations and/or modifications of the basic inventive concepts, which may appear to those skilled in the art, will still fall within the spirit and scope of the present invention as defined in the appended claims.

What is claimed is:

1. A semiconductor package comprising:
a substrate having an upper surface and a lower surface opposite to the upper surface;
a semiconductor chip mounted on the upper surface of the substrate;
an encapsulant sealing the semiconductor chip; and
a heat sink provided on the encapsulant and spaced apart from the substrate, the heat sink having a hole, a portion of the heat sink being exposed by the encapsulant.

2. The semiconductor package of claim 1, wherein the heat sink is superposed above the semiconductor chip.

3. The semiconductor package of claim 1, further comprising connection pads provided on the upper surface of the substrate and on the outside of the encapsulant.

4. The semiconductor package of claim 1, further comprising a plurality of bonding wires connecting the semiconductor chip to the substrate, and wherein the encapsulant seals the bonding wires.

5. The semiconductor package of claim 1, wherein the hole is provided in one of a central area and a peripheral area of the heat sink.

6. The semiconductor package of claim 1, further comprising conductive bumps provided on the lower surface of the substrate.

7. The semiconductor package of claim 1, further comprising:
substrate pads and connection pads provided on the upper surface of the substrate;
bump pads provided on the lower surface of the substrate;
bonding wires electrically connecting the semiconductor chip to the substrate pads; and
conductive bumps provided on the bump pads.

8. The semiconductor package of claim 7, wherein the heat sink is superposed above the bonding wires.

9. The semiconductor package of claim 7, wherein the hole is provided in one of a central area and a peripheral area of the heat sink.

10. A stack package comprising:
the semiconductor package of claim 7; and
an upper package provided on the connection pads of the substrate.

11. The stack package of claim 10, wherein the upper package is a ball grid array semiconductor package with conductive bumps corresponding to the connection pads of the substrate.

12. A method comprising:
providing a substrate supporting a semiconductor chip;
positioning a tape supporting a heat sink above the semiconductor chip, the heat sink having a hole;
providing a liquid molding compound through the hole to seal the semiconductor chip, leaving a portion of the heat sink exposed; and
removing the tape.

13. The method of claim 12, wherein the hole is provided in one of a central area and a peripheral area of the heat sink.

14. The method of claim 13, further comprising:
placing the substrate and the tape in a mold assembly including a top mold, an intermediate mold and a bottom mold.

15. The method of claim 14, further comprising:
drawing a vacuum through the intermediate mold to position the tape so that the heat sink is located in a cavity of the intermediate mold and the hole is connected to a runner of the intermediate mold;
providing the substrate on the bottom mold;
fixing the substrate with engagement of the mold assembly so that the semiconductor chip is located in the cavity of the intermediate mold; and
providing a liquid molding compound in the cavity through the runner of the intermediate and the hole of the heat sink.

16. The method of claim 12, wherein the tape is an ultraviolet tape.

17. The method of claim 16, further comprising irradiating ultraviolet rays onto the tape.

18. The method of claim 12, wherein the substrate has an upper surface supporting connection pads that are provided outside of an encapsulant.

19. The method of claim 18, further comprising providing conductive bumps on a lower surface of the wiring substrate.

20. The method of claim 12, further comprising:
attaching the semiconductor chip to an upper surface of the substrate; and
electrically connecting the semiconductor chip to the substrate via bonding wires.

21. The method of claim 20, further comprising locating the heat sink above the bonding wires.

22. The method of claim 12, wherein the substrate has an upper surface with substrate pads and connection pads, and a lower surface with bump pads; and
wherein the method further comprises:
connecting the semiconductor chip to the substrate pads using bonding wires; and
providing conductive bumps on the bump pads.
